(19) United States
(12) Patent Application Publication
(10) Pub. No.: US 2023/0176477 A1
(43) Pub. Date: Jun. 8, 2023

(54) PHOTORESIST COMPOSITION AND METHOD OF MANUFACTURING INTEGRATED CIRCUIT DEVICE BY USING THE SAME

(71) Applicant: SAMSUNG ELECTRONICS CO., LTD., Suwon-si (KR)

(72) Inventors: Sukkoo HONG, Suwon-si (KR); Moohyun KOH, Hwaseong-si (KR); Kyungoh KIM, Yongin-si (KR); Yechan KIM, Hwaseong-si (KR); Kyunghwan NOH, Seoul (KR); Sungan DO, Hwaseong-si (KR); Hyun-Ji SONG, Suwon-si (KR)

(21) Appl. No.: 17/841,031

(22) Filed: Jun. 15, 2022

(30) Foreign Application Priority Data
Dec. 8, 2021 (KR) 10-2021-0175206

(51) Int. Cl. G03F 7/004; G03F 7/38; H01L 21/027

(52) U.S. Cl. CPC G03F 7/0042; G03F 7/38; H01L 21/0274

(57) ABSTRACT

A photoresist composition includes an organometallic compound including at least one metal-ligand bond, the organometallic compound including a metal core and at least one organic ligand bonded to the metal core, and being configured such that the at least one metal-ligand bond is not breakable by exposure to light or moisture; a photoinitiator generating an acid or a radical in response to exposure to light; and a solvent.

### CROSS-REFERENCE TO RELATED APPLICATION

This application is based on and claims priority under 35 U.S.C. §119 to Korean Patent Application No. 10-2021-0175206, filed on Dec. 8, 2021, in the Korean Intellectual Property Office, the disclosure of which is incorporated by reference herein in its entirety.

### BACKGROUND

### 1. Field

Embodiments relate to a photoresist composition and a method of manufacturing an integrated circuit device by using the photoresist composition.

### 2. Description of the Related Art

Due to the development of electronics technology, semiconductor devices have been rapidly down-scaled. Therefore, photolithography processes having an advantage in implementing fine patterns may be used.

### SUMMARY

The embodiments may be realized by providing a photoresist composition including an organometallic compound including at least one metal-ligand bond, the organometallic compound including a metal core and at least one organic ligand bonded to the metal core, and being configured such that the at least one metal-ligand bond is not breakable by exposure to light or moisture; a photoinitiator generating an acid or a radical in response to exposure to light; and a solvent.

The embodiments may be realized by providing a photoresist composition including an organometallic compound including at least one metal-ligand bond, the organometallic compound including a metal core and at least one organic ligand bonded to the metal core, and being configured such that the at least one metal-ligand bond is not breakable by exposure to light or moisture; a photoinitiator including a photoacid generator (PAG), a photoradical generator (PRG), or a combination thereof; and a solvent, wherein the at least one organic ligand includes a polydentate ligand, and the polydentate ligand includes a quinoline moiety, a β-diketonate moiety, an ethylenediaminetetraacetic acid (EDTA) moiety, a 2,2′-bis(diphenylphosphino)-1,1′-binaphthyl (BINAP) moiety, a salen(2,2′-ethylenebis(nitrilomethylidene)diphenol) moiety, a norbornene dicarboxylic acid moiety, a camphoric acid moiety, or derivatives thereof.

The embodiments may be realized by providing a method of manufacturing an integrated circuit device, the method including forming a photoresist film on a substrate using a photoresist composition, the photoresist composition including an organometallic compound, a photoinitiator that generates an acid or a radical in response to exposure to light, and a solvent, the organometallic compound including at least one metal-ligand bond, and including a metal core and at least one organic ligand bonded to the metal core, the organometallic compound being configured such that the at least one metal-ligand bond is not breakable by exposure to light or moisture; generating an acid or a radical from the photoinitiator in a first region by exposing the first region, which is a portion of the photoresist film; forming a metal structure network in the first region by inducing a dissociation reaction of the at least one organic ligand from the organometallic compound in the first region by use of an acid or a radical, which is generated from the photoinitiator through baking of the photoresist film including the exposed first region, and by inducing a condensation reaction of a hydroxyl (-OH) functional group generated at a site from which the at least one organic ligand is desorbed in the organometallic compound; and forming a photoresist pattern including the metal structure network by developing the photoresist film, in which the metal structure network is formed.

### BRIEF DESCRIPTION OF THE DRAWINGS

Features will be apparent to those of skill in the art by describing in detail exemplary embodiments with reference to the attached drawings in which:

FIG. 1 is a flowchart of a method of manufacturing an integrated circuit device, according to embodiments; and

FIGS. 2A to 2F are cross-sectional views of stages in a method of manufacturing an integrated circuit device, according to embodiments.

### DETAILED DESCRIPTION

A photoresist composition according to embodiments may include, e.g., an organometallic compound including at least one metal-ligand bond; a photoinitiator; and a solvent. In an implementation, the organometallic compound may include, e.g., a metal core and at least one organic ligand bonded to the metal core. In the photoresist composition according to embodiments, the at least one metal-ligand bond of the organometallic compound may not to be broken by exposure to light or moisture. The photoinitiator may generate an acid or a radical by light.

In the photoresist composition according to embodiments, the organometallic compound may include a metal-ligand bond having sufficiently strong bonding strength so as not to be broken, even when exposed to light of a KrF excimer laser (248 nm), an ArF excimer laser (193 nm), an F₂ excimer laser (157 nm), or an extreme ultraviolet (EUV) laser (13.5 nm) or when exposed to moisture in air.

In an implementation, the at least one organic ligand included in the organometallic compound may include a ligand functioning as a relatively strong electron donor, and the ligand may form a strong coordination bond with the metal core and thus provide a relatively strong metal-ligand bond in the organometallic compound.

In an implementation, the at least one organic ligand included in the organometallic compound may include a polydentate ligand having a structure that provides a plurality of metal-ligand binding sites. When the organic ligand is a polydentate ligand, even if one of the plurality of metal-ligand binding sites were to be separated from the metal core, the remaining binding sites may be maintained bonded to the metal core, thereby allowing bonding between the metal core and the organic ligand to be maintained and also helping the separated binding site be re-bonded to the metal core. As such, in the organometallic compound including a ligand, which functions as a relatively strong electron donor, and/or a polydentate ligand, the bonding stability between the metal core and the at least one organic ligand is secured, and a ligand may be suppressed from being dissociated from the metal-ligand bond, even when the organometallic compound is exposed to light or moisture, and thus, the metal-ligand bond may be stably maintained.

In the photoresist composition according to embodiments, the metal core included in the organometallic compound may include at least one metal element. The at least one metal element may be in the form of a metal atom, a metallic ion, a metal compound, a metal alloy, or a combination thereof. The metal compound may include, e.g., a metal oxide, a metal nitride, a metal oxynitride, a metal silicide, a metal carbide, or a combination thereof. In an implementation, the metal core may include, e.g., Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe. As used herein, the term “or” is not an exclusive term, e.g., “A or B” would include A, B, or A and B.

In an implementation, in the photoresist composition, the at least one organic ligand included in the organometallic compound may include a monodentate ligand and may have a structure functioning as a relatively strong electron donor.

In an implementation, the at least one organic ligand included in the organometallic compound may include an organic ligand represented by General Formula 1.

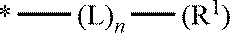

In General Formula 1, L may be a divalent linking group, e.g., —O—, —S—, —SO—, —SO₂—, —CO—, —O—CO—O—, —C(═O)O—, —OCO—, or combinations thereof.

R¹ may be or may include, e.g., a C1 to C30 linear alkyl group, a C1 to C30 branched alkyl group, a C2 to C30 alkenyl group, a C2 to C30 alkynyl group, a C3 to C30 cycloalkyl group, a C1 to C30 alkoxy group, a C6 to C30 aryl group, a C2 to C30 heteroaryl group, a C7 to C30 alkylaryl group, a disubstituted phosphoric acid group, an R²COO- group, an R²SO₃— group, an R²SO₂— group, or a combination thereof, in which R² may be, e.g., a substituted or unsubstituted C1 to C10 alkyl group or a substituted or unsubstituted phenyl group.

n may be, e.g., 0 or 1.

* represents a linkage site to the metal core.

In General Formula 1, R¹ may include, e.g., a hydrocarbyl group substituted with a heteroatom functional group, which may include an oxygen atom, a nitrogen atom, a halogen element, a cyano group, a thio group, a silyl group, an ether group, a carbonyl group, an ester group, a nitro group, an amino group, or a combination thereof. The halogen element may be, e.g., F, Cl, Br, or I.

In an implementation, the organic ligand represented by General Formula 1 may include, e.g., a methyl group, an ethyl group, a propyl group, a butyl group, an isopropyl group, a tert-butyl group, a tert-amyl group, a sec-butyl group, a cyclopropyl group, a cyclobutyl group, a cyclopentyl group, or a cyclohexyl group.

In an implementation, the organic ligand represented by General Formula 1 may include an acid group, e.g., a hydroxyl group, a sulfonate group, a carboxyl group, or a phosphonate group.

In an implementation, the organic ligand represented by General Formula 1 may include, e.g., a CF₃COO— ligand, a CF₃SO₃— ligand, a CF₂CF₂SO₃— ligand, a CF₃CF₂(CF₃)₂CO— ligand, a CF₃SO₂— ligand, a p-toluenesulfonyl ligand, or a diethyl phosphate ligand.

In an implementation, the organic ligand represented by General Formula 1 may include, e.g., an aromatic ring, a heteroaromatic ring, or a combination thereof. The aromatic ring may include a single aromatic ring, e.g., benzene; a heteroaryl group, such as pyridine, pyrimidine, or thiophene; a condensed aryl group, e.g., quinolone, isoquinoline, naphthalene, anthracene, or phenanthrene; or the like. The heteroaryl group and the condensed aryl group may each include a heteroatom, e.g., an O atom, an S atom, or an N atom.

In an implementation, the organic ligand represented by General Formula 1 may include, e.g., one of the following structural units. In the following structural units, * represents a binding site.

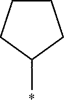

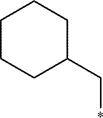

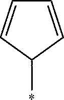

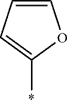

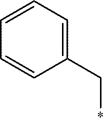

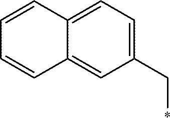

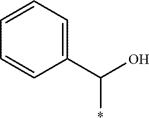

In an implementation, the organic ligand represented by General Formula 1 may include, e.g., a moiety including one of the following structural units.

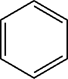

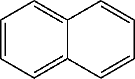

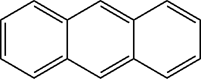

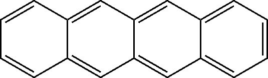

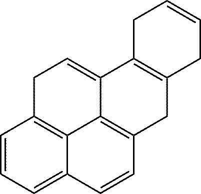

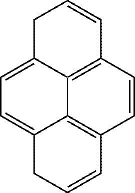

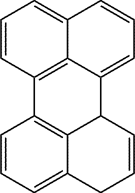

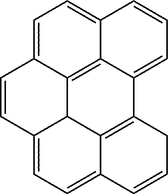

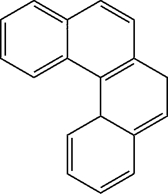

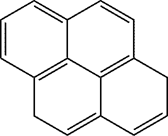

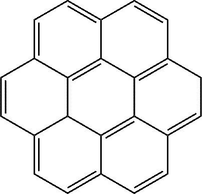

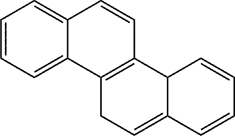

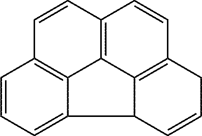

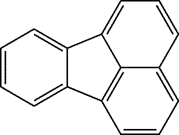

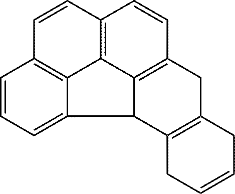

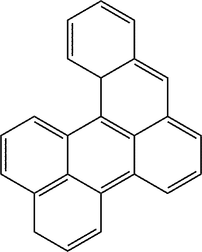

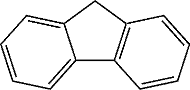

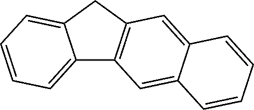

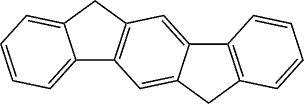

In an implementation, the organometallic compound may include a plurality of organic ligands, and each of the plurality of organic ligands may include a monodentate ligand. In an implementation, the organometallic compound may be, e.g., represented by General Formula 2.

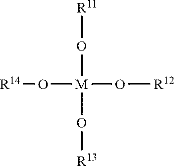

In General Formula 2, M may be, e.g., Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe

R¹¹, R¹², R¹³, and R¹⁴ may each independently be defined the same as R¹ of General Formula 1.

In an implementation, R¹¹, R¹², R¹³, and R¹⁴ may respectively have the same structures as each other. In an implementation, at least some of R¹¹, R¹², R¹³, and R¹⁴ may have different structures from each other.

In an implementation, the at least one organic ligand included in the organometallic compound may include a polydentate ligand. The polydentate ligand may include, e.g., a bidentate ligand including two coordinatable atoms, a tridentate ligand including three coordinatable atoms, or a tetradentate ligand including four coordinatable atoms.

In an implementation, the polydentate ligand may include a structure (e.g., moiety) of, e.g., quinoline, β-diketonate, ethylenediaminetetraacetic acid (EDTA), 2,2′-bis(diphenylphosphino)-1,1′-binaphthyl (BINAP), salen (2,2′-ethylenebis(nitrilomethylidene)diphenol), norbornene dicarboxylic acid, camphoric acid, or derivatives thereof.

When the organometallic compound includes an organic ligand including a quinoline moiety or a quinoline derivative, the organic ligand may be represented by General Formula 3.

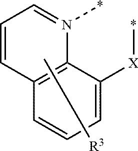

In General Formula 3, R³ may be or may include, e.g., a hydrogen atom, a C1 to C20 linear alkyl group, a C3 to C20 branched alkyl group, a C2 to C20 alkenyl group, a C2 to C20 alkynyl group, a C3 to C20 cycloalkyl group, a C1 to C20 alkoxy group, a C6 to C20 aryl group, or a C2 to C20 heteroaryl group.

X may be, e.g., an O atom or an S atom.

Each * represents a linkage site to the metal core.

In an implementation, the organometallic compound may be, e.g., represented by General Formula 4.

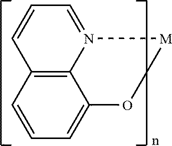

In General Formula 4, M may be defined the same as that of General Formula 2.

n may be, e.g., an integer of 1 to 4.

When the organometallic compound includes an organic ligand including a β-diketonate moiety or a β-diketonate derivative, the organic ligand may include, e.g., acetylacetone, hexafluoroacetylacetone, acetylacetate, diketone, benzoylacetone, 4,4,4-trifluoro-1-phenyl-1,3-butanedionate, ethyl acetoacetate, dibenzoylmethane, or a combination thereof.

In an implementation, the organometallic compound may be, e.g., represented by General Formula 5.

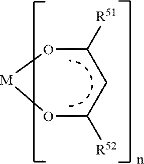

In General Formula 5, M may be defined the same as that of General Formula 2.

R⁵¹ and R⁵² may each independently be or include, e.g., a C1 to C10 linear alkyl group, a C3 to C10 branched alkyl group, a C2 to C10 alkenyl group, a C2 to C10 alkynyl group, a C3 to C10 cycloalkyl group, a C1 to C10 alkoxy group, a C6 to C20 aryl group, or a C2 to C20 heteroaryl group.

n may be, e.g., an integer of 1 to 4.

When the organometallic compound includes an organic ligand including a norbornene dicarboxylic acid moiety, the organometallic compound may be, e.g., represented by General Formula 6.

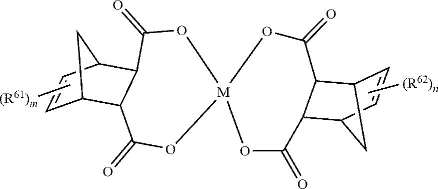

In General Formula 6, M may be defined the same as that of General Formula 2.

R⁶¹ and R⁶² may each independently be or include, e.g., a hydrogen atom, a C1 to C20 linear alkyl group, a C3 to C20 branched alkyl group, a C2 to C20 alkenyl group, a C2 to C20 alkynyl group, a C3 to C20 cycloalkyl group, a C1 to C20 alkoxy group, a C6 to C20 aryl group, or a C2 to C20 heteroaryl group.

m and n may each independently be, e.g., an integer of 0 to 4.

In the photoresist composition according to embodiments, the metal core may be present in an amount of about 0.1% by weight (wt%) to about 5 wt%, based on a total weight of the photoresist composition.

The organometallic compound included in the photoresist composition according to embodiments may have a structure having a relatively strong coordination bond between a metal and an organic ligand to overcome a limit of other organometallic compounds, e.g., which may be easily hydrolyzed by light or by moisture from the air. The organometallic compound included in the photoresist composition according to embodiments may be commercially available or may be obtained from a suitable precursor through synthesis by using a suitable method.

In the photoresist composition according to embodiments, after a photoresist film obtained from the photoresist composition is exposed, the photoinitiator may generate an acid or a radical by absorbing light in an exposed region of the photoresist film. The acid or the radical generated from the photoinitiator may react with an organic ligand of the organometallic compound and thus may induce a dissociation reaction of the organic ligand. Accordingly, the organic ligand may be desorbed from the organometallic compound by the acid or the radical generated from the photoinitiator, and after the organic ligand is desorbed, a hydroxyl (—OH) functional group may be generated at a site from which the organic ligand has been desorbed from the organometallic compound. A condensation reaction of the hydroxyl (—OH) functional group may be induced by a subsequent bake process, and as a result, a network (referred to as a “metal structure network” hereinafter) including a cross-linked structure (e.g., an M-O-M cross-linked structure) including a plurality of metals (M) may be densely formed.

When a photoresist film obtained from the photoresist composition according to embodiments is exposed, the photoinitiator included in the photoresist composition may supplement the relatively low reactivity of the organometallic compound, and the photosensitivity in an exposed region of the photoresist film may be adjusted by the amount of the photoinitiator. In the organometallic compound, the metal-ligand bond may not be broken in response to exposure to light or moisture, the organometallic compound may have relatively low reactivity, an unintended side reaction of the organometallic compound may be minimized in a non-exposed region of the photoresist film, and a ligand dissociation reaction of the organometallic compound may be accelerated in the exposed region by using the acid or the radical generated from the photoinitiator, thereby inducing a photoreaction to be limitedly performed only in the exposed region of the photoresist film.

The photoinitiator may include, e.g., a photoacid generator (PAG) generating an acid by light, a photoradical generator (PRG) generating a radical by light, or a combination of a PAG and a PRG.

The PAG may generate an acid when exposed to light of, e.g., a KrF excimer laser (248 nm), an ArF excimer laser (193 nm), an F₂ excimer laser (157 nm), or an EUV laser (13.5 nm). In an implementation, the PAG may include, e.g., triarylsulfonium salts, diaryliodonium salts, sulfonates, or mixtures thereof. In an implementation, the PAG may include, e.g., triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

When the PRG is exposed to light of, e.g., a KrF excimer laser (248 nm), an ArF excimer laser (193 nm), an F₂ excimer laser (157 nm), or an EUV laser (13.5 nm), the PRG may absorb the light and generate a radical, thereby starting the polymerization of the organometallic compound included in the photoresist composition according to embodiments. In an implementation, the PRG may include, e.g., an acylphosphine oxide compound, an oxime ester compound, or the like.

The acylphosphine oxide compound may include, e.g., 2,4,6-trimethylbenzoyldiphenylphosphine oxide, bis(2,4,6-trimethylbenzoyl)-phenylphosphine oxide, bis(2,6-dimethoxybenzoyl)-(2,4,4-trimethylpentyl)phosphine oxide, or the like.

The oxime ester compound may include, e.g., 1-phenylpropane-1,2-dione-2-(O-ethoxycarbonyl)oxime, 1-phenylbutane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-(carboxyphenyl)thio]phenyl]propane-1,2-dione-2-(O-acetyl)oxime, 1-[9-ethyl-6-(2-methylbenzoyl)-9H-carbazol-3-yl]ethanone-1-(O-acetyl)oxime, 1-[9-ethyl-6-[2-methyl-4-[1-(2,2-dimethyl-1,3-dioxolane-4-yl)methyloxy]benzoyl]-9H-carbazol-3-yl] ethanone-1-(O-acetyl)oxime, or the like.

In an implementation, a commercially available product, e.g., IRGACURE 651, IRGACURE 184, IRGACURE 1173, IRGACURE 2959, IRGACURE 127, IRGACURE 907, IRGACURE 369, IRGACURE 379, IRGACURE TPO, IRGACURE 819, IRGACURE OXE01, IRGACURE OXE02, IRGACURE MBF, or IRGACURE 754 (which is a product model of BASF Co., Ltd.), may be used as the PRG.

The photoresist composition according to an embodiment may include, as the photoinitiator, e.g., a single material selected from the PAGs and the PRGs set forth above, or at least two materials selected from the PAGs and the PRGs set forth above. In an implementation, in the photoresist composition, the photoinitiator may be present in an amount of, e.g., about 2 mol% to about 60 mol%, based on a total amount of moles of the organometallic compound.

The solvent included in the photoresist composition may include an organic solvent. The organic solvent may include, e.g., ethers, alcohols, glycol ethers, aromatic hydrocarbon compounds, ketones, or esters. In an implementation, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbion: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxy acetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl 2-hydroxyisobutyrate, methoxybenzene, n-butyl acetate, 1-methoxy-2-propyl acetate, methoxyethoxy propionate, ethoxyethoxy propionate, or a combination thereof.

In the photoresist composition according to embodiments, the solvent may be present in a remaining or balance amount, except amounts of main components including the organometallic compound and the photoinitiator. In an implementation, the solvent may be present in an amount of about 0.1 wt% to about 99.8 wt%, based on the total weight of the photoresist composition.

In an implementation, when the photoresist composition includes the PAG as the photoinitiator, the photoresist composition may further include a basic quencher.

The basic quencher may include a compound capable of trapping an acid in a non-exposed region of a photoresist film, when the acid generated from the PAG included in the photoresist composition according to embodiments or the acid generated from another photolabile compound diffuses into the non-exposed region. The photoresist composition according to embodiments may include the basic quencher, thereby suppressing a diffusion rate of an acid in the photoresist film obtained from the photoresist composition.

In an implementation, the basic quencher may include, e.g., primary aliphatic amines, secondary aliphatic amines, tertiary aliphatic amines, aromatic amines, heteroaromatic ring-containing amines, nitrogen-containing compounds having carboxyl groups, nitrogen-containing compounds having sulfonyl groups, nitrogen-containing compounds having hydroxyl groups, nitrogen-containing compounds having hydroxyphenyl groups, alcoholic nitrogen-containing compounds, amides, imides, carbamates, or ammonium salts. In an implementation, the basic quencher may include, e.g., triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or a combination thereof.

In an implementation, the basic quencher may include, e.g., a photobase generator. The photobase generator may generate a base by absorbing active energy rays through light irradiation and thus undergoing the decomposition of a chemical structure thereof. Accordingly, when a certain region of a photoresist film formed of the photoresist composition, which includes the basic quencher including the photobase generator, is exposed, the sensitivity in the exposed region may be adjusted by trapping an acid by the photobase generator in the exposed region of the photoresist film, and an acid may be suppressed from diffusing from the exposed region into a non-exposed region. Therefore, a metal structure network, which includes a metal oxide including the metal core, may be selectively formed only in the exposed region of the photoresist film, and adverse effects due to unintended diffusion of the acid, such as the deterioration of critical dimension (CD) distribution in an edge of a photoresist pattern obtained after a development process, may be reduced or prevented.

In an implementation, the material constituting the photobase generator may be a suitable material, e.g., a material generating a base through light irradiation. In an implementation, the photobase generator may include, e.g., a nonionic photobase generator. In an implementation, the photobase generator may include, e.g., an ionic photobase generator.

In an implementation, the photobase generator may include, e.g., a carboxylate or sulfonate salt of a photolabile cation. In an implementation, the photolabile cation included in the photobase generator may include a sulfonium cation. The sulfonium cation may include, e.g., a substituted or unsubstituted C1 to C12 alkyl group, a substituted or unsubstituted C3 to C12 cycloalkyl group, a C6 to C30 aryl group, or a C2 to C30 heteroaryl group. The alkyl group, the cycloalkyl group, the aryl group, and the heteroaryl group may each include at least one heteroatom, e.g., an O atom, an S atom, or an N atom. In an implementation, the sulfonium cation may include, e.g., a phenyl group, a cyclopentyl group, a cyclohexyl group, an adamantyl group, a methyl group, an ethyl group, a propyl group, a butyl group, a t-butyl group, or an isopropyl group.

The photolabile cation included in the photobase generator may form a complex with an anion of a C1 to C20 carboxylic acid. The carboxylic acid may include, e.g., formic acid, acetic acid, propionic acid, tartaric acid, succinic acid, cyclohexanecarboxylic acid, benzoic acid, or salicylic acid.

In an implementation, triphenylsulfonium heptafluorobutyric acid or triphenyl sulfonium hexafluoroantimonate (TPS—SbF6) may be used as the photobase generator.

In an implementation, in the photoresist composition, the basic quencher may be used alone, or a mixture of at least two basic quenchers may be used. The basic quencher may be present in an amount of, e.g., about 0 mol% to about 50 mol%, based on the total number of moles of the organometallic compound.

In an implementation, when the photoresist composition includes the PRG as the photoinitiator, the photoresist composition may further include a radical quencher capable of trapping a radical.

In an implementation, the radical quencher may include, e.g., a quinone free radical or a nitroxide (IUPAC name: aminoxyl) free radical.

The quinone free radical may include, e.g., p-benzoquinone, hydroquinone (1,4-dihydroxybenzene), hydroquinone monomethyl ether (4-methoxyphenol), hydroquinone monomethyl ether, hydroquinone monophenyl ether, mono-t-butyl hydroquinone (MTBHQ), di-t-butyl hydroquinone, di-t-amyl hydroquinone, toluhydroquinone, p-benzoquinone dioxime, 2,6-dichloro-1,4-benzoquinone, 2,3,5,6-tetramethyl-1,4-benzoquinone, 2,5-dichloro-3,6-dihydroxy-p-benzoquinone, methyl-p-benzoquinone, 6-anilinoquinoline-5,8-quinone, pyrroloquinoline quinone, 2-allyl-6-methoxybenzo-1,4-quinone, or a combination thereof.

The nitroxide free radical may include, e.g., di-tert-butyl nitroxide (DTBN), 2,2,6,6-tetramethyl-1-peperidine 1-oxyl (TEMPO), oxo TEMPO (4-oxo-2,2,6,6-tetramethyl-1-peperidine 1-oxyl), 1,1,3,3-tetraethylisoindolin-N-oxyl, N-tert-butyl-N-[1-(diethoxyphosphoryl)-2,2-dimethylpropyl]aminoxyl (SG1), (N-tert-butyl-N-(2-methyl-1-phenylpropyl) aminoxyl (TIPNO), or a combination thereof.

When a photolithography process is performed by using the photoresist composition according to an embodiment, a radical generated from the PRG in an exposed region of a photoresist film obtained from the photoresist composition may be quenched by the radical quencher, the sensitivity in the exposed region may be adjusted, and a radical coming into a non-exposed region from the exposed region may be quenched by the radical quencher. Therefore, a network, which includes a metal oxide including the metal core, may be selectively formed only in the exposed region, and adverse effects due to unintended diffusion of the radical, such as the deterioration of CD distribution in an edge of a photoresist pattern obtained after a development process, may be reduced or prevented.

In an implementation, in the photoresist composition, the radical quencher may be used alone, or a mixture of at least two radical quenchers may be used. The radical quencher may be present in an amount of about 0 mol% to about 50 mol%, based on the total number of moles of the organometallic compound.

In an implementation, the photoresist composition may further include, e.g., a leveling agent, a surfactant, a dispersant, a moisture absorbent, or a coupling agent.

The leveling agent may help improve coating flatness when the photoresist composition is coated on a substrate, and a suitable or commercially available leveling agent may be used.

The surfactant may help improve the coating uniformity and wettability of the photoresist composition. In an implementation, the surfactant may include, e.g., a sulfuric acid ester salt, a sulfonic acid salt, phosphoric acid ester, soap, an amine salt, a quaternary ammonium salt, polyethylene glycol, an alkylphenol ethylene oxide adduct, a polyhydric alcohol, a nitrogen-containing vinyl polymer, or a combination thereof. For example, the surfactant may include an alkylbenzene sulfonate, an alkyl pyridinium salt, polyethylene glycol, or a quaternary ammonium salt. When the photoresist composition includes the surfactant, the surfactant may be present in an amount of about 0.001 wt% to about 3 wt%, based on the total weight of the photoresist composition.

The dispersant may facilitate uniform dispersion of the respective components constituting the photoresist composition in the photoresist composition. In an implementation, the dispersant may include, e.g., an epoxy resin, polyvinyl alcohol, polyvinyl butyral, polyvinylpyrrolidone, glucose, sodium dodecyl sulfate, sodium citrate, oleic acid, linoleic acid, or a combination thereof. When the photoresist composition includes the dispersant, the dispersant may be present in an amount of, e.g., about 0.001 wt% to about 5 wt%, based on the total weight of the photoresist composition.

The moisture absorbent may help prevent adverse effects due to moisture in the photoresist composition. In an implementation, the moisture absorbent may include, e.g., polyoxyethylene nonylphenol ether, polyethylene glycol, polypropylene glycol, polyacrylamide, or a combination thereof. When the photoresist composition includes the moisture absorbent, the moisture absorbent may be present in an amount of about 0.001 wt% to about 10 wt%, based on the total weight of the photoresist composition.

The coupling agent may help improve adhesion to a lower film when the photoresist composition is coated on the lower film. In an implementation, the coupling agent may include, e.g., a silane coupling agent. The silane coupling agent may include, e.g., vinyltrimethoxysilane, vinyltriethoxysilane, vinyltrichlorosilane, vinyltris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy[3-(phenylamino)propyl]silane. When the photoresist composition includes the coupling agent, the coupling agent may be present in an amount of about 0.001 wt% to about 5 wt%, based on the total weight of the photoresist composition.

In an implementation, in the photoresist composition, when the solvent includes only an organic solvent, the photoresist composition may further include water. In this case, water may be present in an amount of about 0.001 wt% to about 0.1 wt%, based on the total weight of the photoresist composition.

The photoresist composition according to embodiments may include the organometallic compound, which may have a structure having a relatively strong coordination bond between the metal core and the organic ligand such that the metal-ligand bond is not broken by light or by moisture in air. Therefore, when a photoresist film obtained from the photoresist composition is exposed, the organometallic compound may function only to transfer electrons, and the dissociation of a ligand due to light may not occur in the organometallic compound. To supplement the relatively low reactivity of the organometallic compound, the photoresist composition according to embodiments may further include a photoinitiator. The photoinitiator in an exposed region of the photoresist film may generate an acid or a radical by absorbing active energy rays and thus by undergoing the decomposition of a chemical structure thereof, and the acid or the radical generated from the photoinitiator may induce a dissociation reaction of an organic ligand in the organometallic compound. After the organic ligand is desorbed by the photoinitiator, a hydroxyl (—OH) functional group may be generated at a site from which the organic ligand has been desorbed from the organometallic compound. A condensation reaction of the hydroxyl (—OH) functional group may then be induced by a subsequent bake process. As a result, a metal structure network having a dense structure may be selectively obtained only in the exposed region of the photoresist film, and the metal structure network may not be formed in a non-exposed region of the photoresist film. Accordingly, a difference in solubility in a developer between the exposed region and the non-exposed region of the photoresist film may be increased. Therefore, in manufacturing an integrated circuit device by using the photoresist composition according to embodiments, excellent resolution and improved sensitivity in a photolithography process may be provided, and in forming a pattern needed for the integrated circuit device, the dimensional precision of the pattern intended to be formed may be improved by preventing the deterioration in CD distribution of the pattern.

The photoresist composition according to an embodiment may be advantageously used in forming a pattern having a relatively high aspect ratio. In an implementation, the photoresist composition may be advantageously used in a photolithography process for forming a pattern having a fine width selected from a range of about 5 nm to about 100 nm.

Next, a method of manufacturing an integrated circuit device by using the photoresist composition according to embodiments will be described.

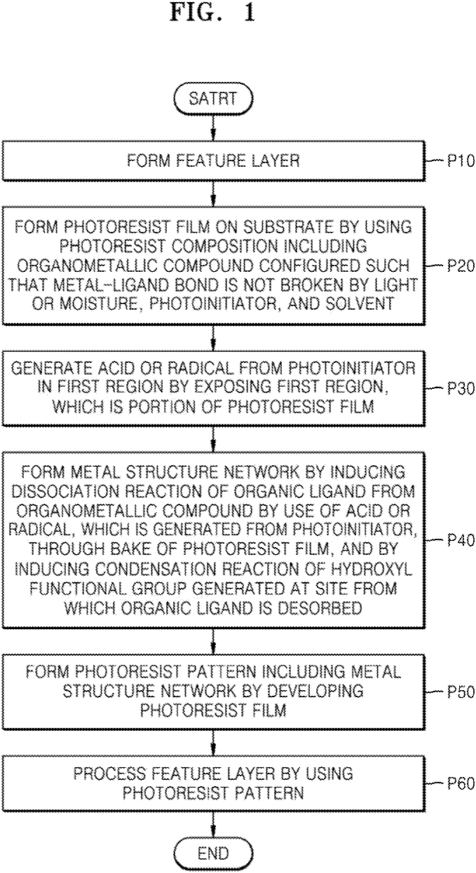

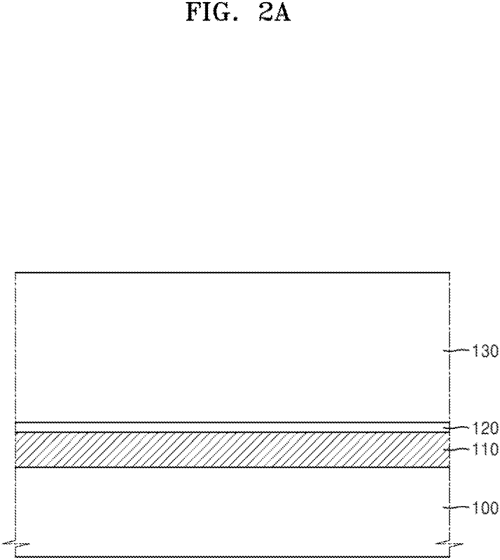

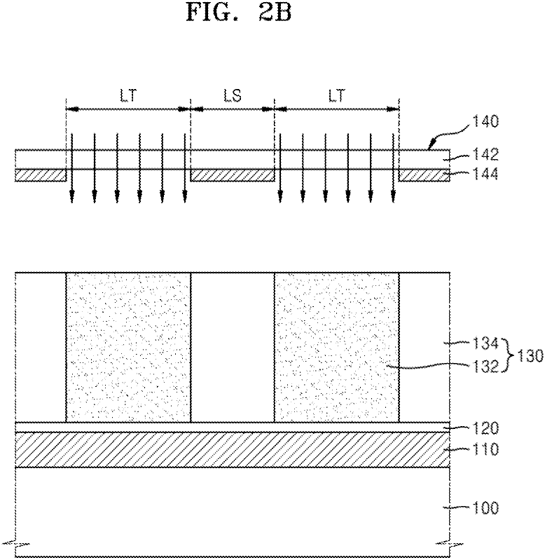

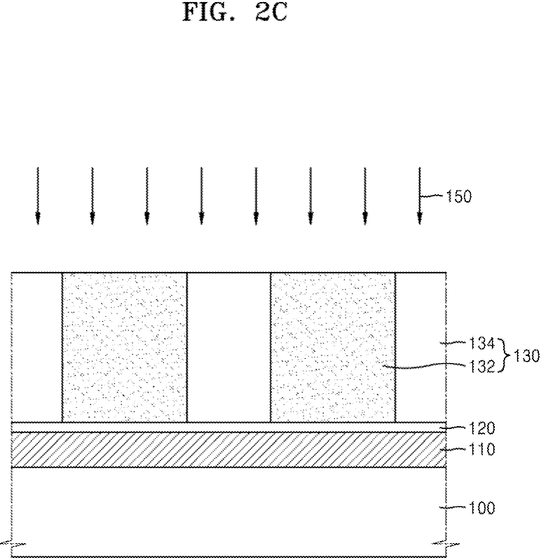

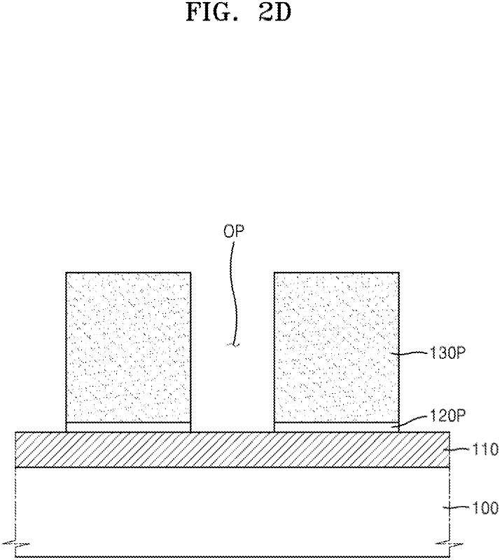

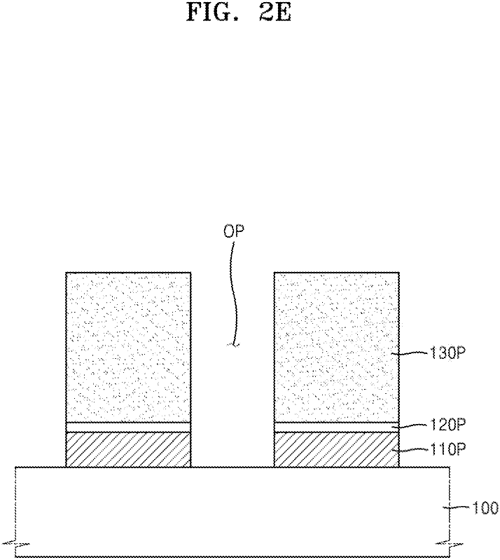

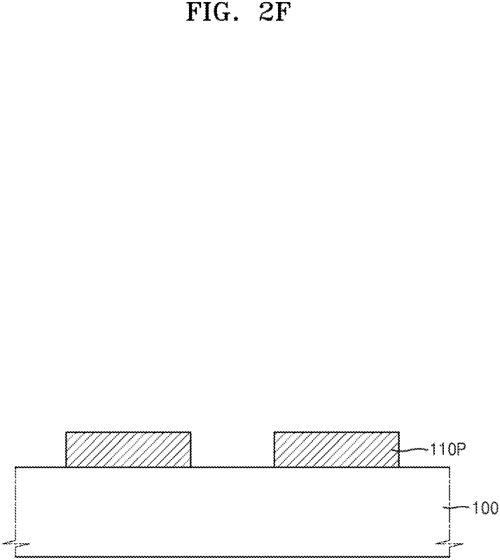

FIG. 1 is a flowchart of a method of manufacturing an integrated circuit device, according to embodiments. FIGS. 2A to 2F are cross-sectional views of stages in a method of manufacturing an integrated circuit device, according to embodiments.

Referring to FIGS. 1 and 2A, in a process P10, a feature layer 110 may be formed on a substrate 100. Next, in a process P20, a photoresist film 130 may be formed on the feature layer 110 by using the photoresist composition according to embodiments. More detailed descriptions of the photoresist composition are the same as given above.

The substrate 100 may include a semiconductor substrate. The feature layer 110 may include an insulating film, a conductive film, or a semiconductor film. In an implementation, the feature layer 110 may include, e.g., a metal, an alloy, a metal carbide, a metal nitride, a metal oxynitride, a metal oxycarbide, a semiconductor, polysilicon, an oxide, a nitride, an oxynitride, or a combination thereof.

In an implementation, as shown in FIG. 2A, before the photoresist film 130 is formed on the feature layer 110, a lower film 120 may be formed on the feature layer 110. In this case, the photoresist film 130 may be formed on the lower film 120. The lower film 120 may help prevent the photoresist film 130 from being adversely affected by the feature layer 110 under the photoresist film 130. In an implementation, the lower film 120 may include an organic or inorganic anti-reflective coating (ARC) material for KrF excimer lasers, ArF excimer lasers, EUV lasers, or other suitable light sources. In an implementation, the lower film 120 may include a bottom anti-reflective coating (BARC) film or a developable bottom anti-reflective coating (DBARC) film. In an implementation, the lower film 120 may include an organic component having a light absorption structure. The light absorption structure may include, e.g., a hydrocarbon compound having a structure in which one or more benzene rings are fused. The lower film 120 may have, e.g., a thickness of about 1 nm to about 100 nm. In an implementation, the lower film 120 may be omitted.

To form the photoresist film 130, the photoresist composition according to embodiments may be coated on the lower film 120 and then treated with heat. The coating may be performed by, e.g., spin coating, spray coating, dip coating, or the like. In an implementation, a process of heat-treating the photoresist composition may be performed, e.g., at a temperature of about 80° C. to about 300° C. for about 10 seconds to about 100 seconds. The thickness of the photoresist film 130 may be tens to hundreds of times the thickness of the lower film 120. The photoresist film 130 may have, e.g., a thickness of about 10 nm to about 1 µm.

The organometallic compound included in the photoresist composition according to embodiments may include at least one metal-ligand bond, e.g., may be a compound including a metal core and at least one organic ligand bonded to the metal core. The at least one organic ligand may include a ligand functioning as a relatively strong electron donor. In an implementation, the ligand may be, e.g., a polydentate ligand. In an implementation, the bonding stability between the metal core and the at least one organic ligand in the organometallic compound may be secured. Therefore, while the photoresist film 130 is formed according to the description made regarding the process P20 of FIG. 1 with reference to FIG. 2A, or during a time period for waiting for a subsequent process after the photoresist film 130 is formed, even when the photoresist film 130 is exposed to light or to moisture in air, a ligand may be suppressed from being dissociated from the metal ligand bond, and thus, the metal-ligand bond may be stably maintained.

Referring to FIGS. 1 and 2B, in a process P30, an acid or a radical may be generated from a photoinitiator included in the photoresist film 130 in a first region 132 by exposing the first region 132, which is a portion of the photoresist film 130.

The photoinitiator included in the photoresist film 130 may include a PAG generating an acid due to light, a PRG generating a radical due to light, or a combination of a PAG and a PRG. In an implementation, while the first region 132 of the photoresist film 130 is exposed according to the process P30 of FIG. 1, the photoinitiator included in the photoresist film 130 in the first region 132 may absorb light and thus generate an acid or a radical.

In an implementation, to expose the first region 132 of the photoresist film 130, a photomask 140, which has a plurality of light shielding areas LS and a plurality of light transmitting areas LT, may be aligned at a certain position over the photoresist film 130, and the first region 132 of the photoresist film 130 may be exposed through the plurality of light transmitting areas LT of the photomask 140. To expose the first region 132 of the photoresist film 130, e.g., a KrF excimer laser (248 nm), an ArF excimer laser (193 nm), an F₂ excimer laser (157 nm), or an EUV laser (13.5 nm) may be used.

In an implementation, the photomask 140 may include a transparent substrate 142, and a plurality of light shielding patterns 144 in the plurality of light shielding areas LS on the transparent substrate 142. The transparent substrate 142 may include quartz. The plurality of light shielding patterns 144 may include chromium (Cr). The plurality of light transmitting areas LT may be defined by (e.g., between) the plurality of light shielding patterns 144. In an implementation, to expose the first region 132 of the photoresist film 130, a reflective photomask for EUV exposure may be used instead of the photomask 140.

When the first region 132 of the photoresist film 130 is exposed, an acid or a radical may be generated from the photoinitiator in the first region 132 because the photoinitiator in the first region 132 absorbs active energy rays and thus undergoes the decomposition of a chemical structure thereof, the organometallic compound may function only to transfer electrons, and the dissociation of a ligand due to light may not occur in the organometallic compound. The acid or the radical generated from the photoinitiator may have relatively low reactivity and relatively high stability as compared with a radical generated from the organometallic compound, and the dissociation of a ligand due to light may not occur in the organometallic compound when the first region 132 is exposed, unintended diffusion of the acid or the radical generated from the photoinitiator in the first region 132 into a second region 134, which is a non-exposed region adjacent to the first region 132, may be minimized, and an unintended side reaction of the organometallic compound in the second region 134 may be minimized.

Referring to FIGS. 1 and 2C, in a process P40, a bake process may be performed by applying heat 150 to the photoresist film 130 including the exposed first region 132.

The bake process may be performed at a temperature of about 50° C. to about 400° C. for about 10 seconds to about 150 seconds. In an implementation, the bake process may be performed, e.g., at a temperature of about 150° C. to about 250° C. for about 60 seconds to about 120 seconds.

In an implementation, while the bake process of the photoresist film 130 is performed, a dissociation reaction of an organic ligand in the organometallic compound may be induced by using the acid or the radical generated from the photoinitiator in the first region 132, and a condensation reaction of a hydroxyl (—OH) functional group generated at a site, from which the organic ligand has been desorbed, may be induced, thereby forming a metal structure network having a dense structure.

On the other hand, the metal structure network may not be formed in the second region 134, which is a non-exposed region of the photoresist film 130, and thus, a difference in solubility in a developer between the first region 132 and the second region 134 of the photoresist film 130 may be increased.

Referring to FIGS. 1 and 2D, in a process P50, the second region 134 of the photoresist film 130 may be removed by developing the photoresist film 130 by using a developer. As a result, a photoresist pattern 130P, which includes the metal structure network formed in the exposed first region 132 of the photoresist film 130, may be formed.

The photoresist pattern 130P may include a plurality of openings OP. After the photoresist pattern 130P is formed, a lower pattern 120P may be formed by removing portions of the lower film 120, which are exposed by the plurality of openings OP.

In an implementation, the development of the photoresist film 130 may be performed by a negative-tone development (NTD) process.

In an implementation, to develop the photoresist film 130, a developer including an organic solvent may be used. In an implementation, the developer may include, e.g., ketones, such as methyl ethyl ketone, acetone, cyclohexanone, or 2-heptanone; alcohols, such as 4-methyl-2-propanol, 1-butanol, isopropanol, 1-propanol, or methanol; esters, such as propylene glycol monomethyl ether acetate, ethyl acetate, ethyl lactate, n-butyl acetate, or butyrolactone; aromatic compounds, such as benzene, xylene, or toluene; or combinations thereof. As the difference in solubility in the developer between the exposed first region 132 and the non-exposed second region 134 in the photoresist film 130 is increased, as described with reference to FIG. 2C, while the second region 134 is removed by developing the photoresist film 130 in the process of FIG. 2D, the first region 132 may remain as it is without being removed. Therefore, after the photoresist film 130 is developed, a residual defect, e.g., a footing phenomenon, may not occur, and a vertical sidewall profile of the photoresist pattern 130P may be obtained. As such, by improving the sidewall profile of the photoresist pattern 130P, a critical dimension of an intended processing region in the feature layer 110 may be precisely controlled when the feature layer 110 is processed by using the photoresist pattern 130P.

In an implementation, after the photoresist pattern 130P is formed by developing the photoresist film 130, as described with reference to FIG. 2D, a process of performing hard bake on an obtained resulting product may be further performed. Through the hard bake process, unnecessary materials, e.g., the developer remaining on the resulting product, in which the photoresist pattern 130P is formed, may be removed. In addition, during the bake process described regarding the process P40 of FIG. 1 with reference to FIG. 2C, when a generation reaction of an acid or a radical from the photoinitiator, or a dissociation reaction of an organic ligand in the organometallic compound and an additional condensation reaction according thereto are not sufficiently performed, an additional reaction of the unreacted portions may be induced by the hard bake process. Accordingly, the hardness of the photoresist pattern 130P may be further increased by the hard bake process.

The hard bake process may be performed at a temperature of about 50° C. to about 400° C. for about 10 seconds to about 150 seconds. In an implementation, the hard bake process may be performed, e.g., at a temperature of about 150° C. to about 250° C. for about 60 seconds to about 120 seconds.

Referring to FIGS. 1 and 2E, in a process P60, in a resulting product of FIG. 2D, the feature layer 110 may be processed by using the photoresist pattern 130P.

To process the feature layer 110, various processes, e.g., a process of etching the feature layer 110 exposed by an opening OP of the photoresist pattern 130P, a process of implanting impurity ions into the feature layer 110, a process of forming an additional film on the feature layer 110 through the opening OP, and a process of modifying a portion of the feature layer 110 through the opening OP, may be performed. In an implementation, as illustrated in FIG. 2E, the method may include, e.g., a process of processing the feature layer 110, and forming a feature pattern 110P by etching the feature layer 110 exposed by the opening OP.

In an implementation, the process of forming the feature layer 110 may be omitted from the process described with reference to FIG. 2A, and in this case, instead of the process P60 of FIG. 1 and the process described with reference to FIG. 2E, the substrate 100 may be processed by using the photoresist pattern 130P. In an implementation, various processes, e.g., a process of etching a portion of the substrate 100 by using the photoresist pattern 130P, a process of implanting impurity ions into a certain region of the substrate 100, a process of forming an additional film on the substrate 100 through the opening OP, and a process of modifying a portion of the substrate 100 through the opening OP, may be performed.

Referring to FIG. 2F, in a resulting product of FIG. 2E, the photoresist pattern 130P and the lower pattern 120P, which remain on the feature pattern 110P, may be removed. To remove the photoresist pattern 130P and the lower pattern 120P, ashing and strip processes may be used.

According to the method of manufacturing an integrated circuit device, which is described with reference to FIGS. 1 and 2A to 2F, a difference in solubility in a developer between the exposed region and the non-exposed region of the photoresist film 130, which is obtained by using the photoresist composition according to an embodiment, may be increased, and the CD distribution in the photoresist pattern 130P may be improved. Therefore, when a subsequent process is performed on the feature layer 110 or the substrate 100 by using the photoresist pattern 130P, CDs of processing regions or patterns intended to be formed in the feature layer 110 or the substrate 100 may be precisely controlled, thereby improving dimensional precision. In addition, the CD distribution of patterns intended to be implemented on the substrate 100 may be uniformly controlled, and the productivity of a manufacturing process of an integrated circuit device may be improved.

By way of summation and review, photoresist compositions may be capable of providing process stability, excellent etching resistance, and excellent resolution in photolithography processes for manufacturing integrated circuit devices.

One or more embodiments may provide a photoresist composition including a metal.

One or more embodiments may provide a photoresist composition, which may help improve process stability by suppressing a change over time and may provide excellent etching resistance and excellent resolution in a photolithography process for manufacturing an integrated circuit device.

One or more embodiments may provide a method of manufacturing an integrated circuit device, the method allowing process stability to be improved by suppressing a change over time in a photolithography process and allowing dimensional precision of a pattern intended to be formed to be improved by providing excellent etching resistance and excellent resolution in a photolithography process.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photoresist composition, comprising:
an organometallic compound including at least one metal-ligand bond, the organometallic compound including a metal core and at least one organic ligand bonded to the metal core, and being configured such that the at least one metal-ligand bond is not breakable by exposure to light or moisture;
a photoinitiator generating an acid or a radical in response to exposure to light; and
a solvent.

2. The photoresist composition as claimed in claim 1, wherein the at least one organic ligand includes a monodentate ligand.

3. The photoresist composition as claimed in claim 1, wherein the at least one organic ligand includes a polydentate ligand.

4. The photoresist composition as claimed in claim 1, wherein:
the at least one organic ligand includes an organic ligand represented by General Formula 1 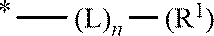
in General Formula 1,
L is —O—, —S—, —SO—, —SO₂—, —CO—, —O—CO—O—, —C(═O)O—, —OCO—, or a combination thereof,
R¹ is a C1 to C30 linear alkyl group, a C3 to C30 branched alkyl group, a C2 to C30 alkenyl group, a C2 to C30 alkynyl group, a C3 to C30 cycloalkyl group, a C1 to C30 alkoxy group, a C6 to C30 aryl group, a C2 to C30 heteroaryl group, a C7 to C30 alkylaryl group, a disubstituted phosphoric acid group, an R²COO— group, an R²SO₃-group, an R²SO₂— group, or a combination thereof, in which R² is a substituted or unsubstituted C1 to C10 alkyl group or a substituted or unsubstituted phenyl group,
n is 0 or 1, and
* represents a linkage site to the metal core.

5. The photoresist composition as claimed in claim 1, wherein:
the at least one organic ligand includes a polydentate ligand, and
the polydentate ligand includes a quinoline moiety, a β-diketonate moiety, an ethylenediaminetetraacetic acid (EDTA) moiety, a 2,2′-bis(diphenylphosphino)-1,1′-binaphthyl (BINAP) moiety, a salen(2,2′-ethylenebis(nitrilomethylidene)diphenol) moiety, a norbornene dicarboxylic acid moiety, a camphoric acid moiety, or derivatives thereof.

6. The photoresist composition as claimed in claim 1, wherein the metal core includes Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe.

7. The photoresist composition as claimed in claim 1, wherein the photoinitiator includes a photoacid generator (PAG) that generates an acid in response to exposure to light.

8. The photoresist composition as claimed in claim 7, further comprising a basic quencher, the basic quencher being a compound capable of trapping an acid.

9. The photoresist composition as claimed in claim 1, wherein the photoinitiator includes a photoradical generator (PRG) that generates a radical in response to exposure to light.

10. The photoresist composition as claimed in claim 9, further comprising a radical quencher, the radical quencher being capable of trapping a radical.

11. A photoresist composition, comprising:
an organometallic compound including at least one metal-ligand bond, the organometallic compound including a metal core and at least one organic ligand bonded to the metal core, and being configured such that the at least one metal-ligand bond is not breakable by exposure to light or moisture;
a photoinitiator including a photoacid generator (PAG), a photoradical generator (PRG), or a combination thereof; and
a solvent, wherein:
the at least one organic ligand includes a polydentate ligand, and
the polydentate ligand includes a quinoline moiety, a β-diketonate moiety, an ethylenediaminetetraacetic acid (EDTA) moiety, a 2,2′-bis(diphenylphosphino)-1,1′-binaphthyl (BINAP) moiety, a salen(2,2′-ethylenebis(nitrilomethylidene)diphenol) moiety, a norbornene dicarboxylic acid moiety, a camphoric acid moiety, or derivatives thereof.

12. The photoresist composition as claimed in claim 11, wherein:
the at least one organic ligand includes a moiety represented by General Formula 3: 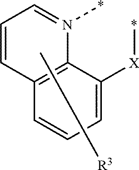
in General Formula 3,
R³ is a hydrogen atom, a C1 to C20 linear alkyl group, a C3 to C20 branched alkyl group, a C2 to C20 alkenyl group, a C2 to C20 alkynyl group, a C3 to C20 cycloalkyl group, a C1 to C20 alkoxy group, a C6 to C20 aryl group, or a C2 to C20 heteroaryl group,
X is an O atom or an S atom, and
each * represents a linkage site to the metal core.

13. The photoresist composition as claimed in claim 11, wherein:
the organometallic compound is represented by General Formula 4: 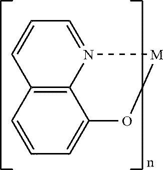
in General Formula 4,
M is Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe, and
n is an integer of 1 to 4.

14. The photoresist composition as claimed in claim 11, wherein:
the organometallic compound is represented by General Formula 5: 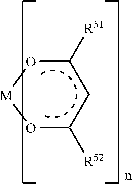
in General Formula 5,
M is Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
R⁵¹ and R⁵² are each independently a C1 to C10 linear alkyl group, a C3 to C10 branched alkyl group, a C2 to C10 alkenyl group, a C2 to C10 alkynyl group, a C3 to C10 cycloalkyl group, a C1 to C10 alkoxy group, a C6 to C20 aryl group, or a C2 to C20 heteroaryl group, and
n is an integer of 1 to 4.

15. The photoresist composition as claimed in claim 11, wherein:
the organometallic compound is represented by General Formula 6: 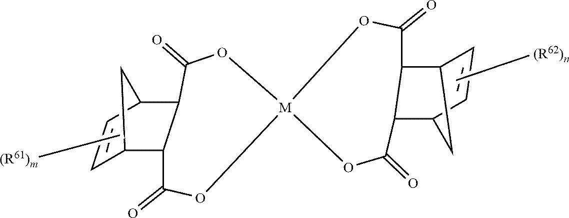
in General Formula 6,
M is Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
R⁶¹ and R⁶² are each independently a hydrogen atom, a C1 to C20 linear alkyl group, a C3 to C20 branched alkyl group, a C2 to C20 alkenyl group, a C2 to C20 alkynyl group, a C3 to C20 cycloalkyl group, a C1 to C20 alkoxy group, a C6 to C20 aryl group, or a C2 to C20 heteroaryl group, and
m and n are each independently an integer of 0 to 4.

16. The photoresist composition as claimed in claim 11, further comprising a basic quencher or a radical quencher, the basic quencher including a compound capable of trapping an acid, and the radical quencher including a compound capable of trapping a radical.

17. A method of manufacturing an integrated circuit device, the method comprising:
forming a photoresist film on a substrate using a photoresist composition, the photoresist composition including an organometallic compound, a photoinitiator that generates an acid or a radical in response to exposure to light, and a solvent, the organometallic compound including at least one metal-ligand bond, and including a metal core and at least one organic ligand bonded to the metal core, the organometallic compound being configured such that the at least one metal-ligand bond is not breakable by exposure to light or moisture;
generating an acid or a radical from the photoinitiator in a first region by exposing the first region, which is a portion of the photoresist film;
forming a metal structure network in the first region by inducing a dissociation reaction of the at least one organic ligand from the organometallic compound in the first region by use of an acid or a radical, which is generated from the photoinitiator through baking of the photoresist film including the exposed first region, and by inducing a condensation reaction of a hydroxyl (—OH) functional group generated at a site from which the at least one organic ligand is desorbed in the organometallic compound; and
forming a photoresist pattern including the metal structure network by developing the photoresist film, in which the metal structure network is formed.

18. The method as claimed in claim 17, wherein, in the exposing of the first region, the at least one organic ligand is not dissociated from the organometallic compound by light.

19. The method as claimed in claim 17, wherein:
the metal core includes Sn, Sb, In, Bi, Ag, Te, Au, Pb, Zn, Ti, Hf, Zr, Al, V, Cr, Co, Ni, Ga, Mn, Cu, Sr, W, Cd, Mo, Ta, Nb, Cs, Ba, La, Ce, or Fe,
the at least one organic ligand includes a polydentate ligand including a quinoline moiety, a β-diketonate moiety, an ethylenediaminetetraacetic acid (EDTA) moiety, a 2,2′-bis(diphenylphosphino)-1,1′-binaphthyl (BINAP) moiety, a salen(2,2′-ethylenebis(nitrilomethylidene)diphenol) moiety, a norbornene dicarboxylic acid moiety, a camphoric acid moiety, or derivatives thereof, and
the photoinitiator includes a photoacid generator (PAG), a photoradical generator (PRG), or a combination thereof.

20. The method as claimed in claim 17, wherein, in the exposing of the first region, the first region is exposed with a KrF excimer laser (248 nm), an ArF excimer laser (193 nm), an F₂ excimer laser (157 nm), or an extreme ultraviolet (EUV) laser (13.5 nm).
